(19) United States
(12) Patent Application Publication
(10) Pub. No.: US 2025/0322889 A1
(43) Pub. Date: Oct. 16, 2025

(54) NONVOLATILE MEMORY DEVICE DETECTING LOW POWER SUPPLY VOLTAGE AND OPERATION METHOD THEREOF

(71) Applicant: Samsung Electronics Co., Ltd., Suwon-si (KR)

(72) Inventors: PHILKYU KANG, Suwon-si (KR); JAE-YUN LEE, Suwon-si (KR); SANG SOO PARK, Suwon-si (KR); YOHAN LEE, Suwon-si (KR)

(21) Appl. No.: 19/005,213

(22) Filed: Dec. 30, 2024

(30) Foreign Application Priority Data
Apr. 12, 2024 (KR) 10-2024-0048986

(51) Int. Cl. G11C 16/26; G11C 16/04; G11C 16/08; G11C 16/24; G11C 16/30

(52) U.S. Cl. CPC G11C 16/26; G11C 16/0483; G11C 16/08; G11C 16/24; G11C 16/30

(57) ABSTRACT

A method of operating a non-volatile memory device may include precharging sensing nodes of a plurality of page buffers based on a reference voltage and latching the sensing nodes to obtain first sensing data, precharging the sensing nodes of the plurality of page buffers based on a power supply voltage and latching the sensing nodes to obtain second sensing data, and comparing the first sensing data and the second sensing data to determine whether a voltage level of the power supply voltage is lower than the reference voltage.

### CROSS-REFERENCE TO RELATED APPLICATIONS

This application claims priority under 35 U.S.C. § 119 to Korean Patent Application No. 10-2024-0048986 filed on Apr. 12, 2024, in the Korean Intellectual Property Office, the disclosure of which is incorporated by reference herein in its entirety.

### BACKGROUND OF THE INVENTION

Embodiments of the present disclosure described herein relate to a semiconductor memory device, and more specifically, to a non-volatile memory device that detects a low-voltage state of a power supply voltage using a sensing node of a page buffer and a method of operating the same.

Semiconductor memory devices can be broadly divided into volatile memory and non-volatile memory. Volatile memory (for example, DRAM or SRAM) has fast reading and writing speeds, but stored data is lost when the power supply is cut off. On the other hand, non-volatile memory such as NAND flash memory can retain stored data even if the power supply is interrupted. Recently, vertical NAND flash memory devices that are stacked in three dimensions to improve integration have been proposed. Vertical NAND flash memory devices may form a NAND cell string by stacking memory cells in the vertical direction of the substrate to improve integration.

Meanwhile, the NAND flash memory device may be left in a powered off state for a long time after storing data. To read data from a flash memory device that has been left in the power-off state for a long period of time, a first read operation may be performed along with power supply. In this case, when memory cells are read at a low power voltage (i.e., Low VCC), hot-carrier-injection (HCI) may occur in the channel of the NAND cell string. When hot-carrier-injection (HCI) occurs, the threshold voltage distribution of memory cells constituting a cell string may change. That is, hot-carrier-injection (HCI) caused by low power supply voltage may rapidly deteriorate the data reliability of the NAND flash memory device.

To address the hot-carrier-injection (HCI) caused by such a low power supply voltage (Low VCC), a method of adjusting a word line voltage slope has been proposed. However, the current consumption of the charge pump driven to set the word line voltage slope may rapidly increase, which can increase power consumption. Therefore, research has been conducted to address the problem of data reliability deterioration in memory cells caused by hot-carrier-injection (HCI) at low power supply voltages without increasing power consumption.

### SUMMARY OF THE INVENTION

Example embodiments of the present disclosure provide a non-volatile memory device that can mitigate the hot-carrier-injection (HCI) phenomenon caused by low power supply voltages and ensure data reliability.

According to aspects of the inventive concepts, a method of operating a non-volatile memory device is provided that comprises precharging sensing nodes of a plurality of page buffers based on a reference voltage and latching the sensing nodes to obtain first sensing data, precharging the sensing nodes of the plurality of page buffers based on a power supply voltage and latching the sensing nodes to obtain second sensing data, and comparing the first sensing data and the second sensing data to determine whether a voltage level of the power supply voltage is lower than the reference voltage.

According to aspects of the inventive concepts, a non-volatile memory device is provided that comprises a cell array including a plurality of NAND cell strings electrically connected to bit lines, a row decoder configured to select a row of the cell array in response to an address, a page buffer circuit including a plurality of page buffers configured to sense memory cells of the selected row through the bit lines, and a control circuit configured to: control the plurality of page buffers to precharge and sense sensing nodes of the plurality of page buffers based on a reference voltage to obtain first sensing data, control the plurality of page buffers to precharge and sense the sensing nodes based on a power supply voltage to obtain second sensing data, perform a low voltage detection operation to determine whether a voltage level of the power supply voltage is lower than the reference voltage based on a comparison between the first sensing data and the second sensing data, and perform a core control operation to lower a channel potential of at least one of the plurality of NAND cell strings when the voltage level of the power supply voltage is lower than the reference voltage.

According to aspects of the inventive concepts, a method of operating a non-volatile memory device is provided that comprises precharging sensing nodes of a plurality of page buffers based on a reference voltage, latching data of the sensing nodes precharged based on the reference voltage to obtain first sensing data, precharging the sensing nodes of the plurality of page buffers based on a power supply voltage, latching data of the sensing nodes precharged based on the power supply voltage to obtain second sensing data, comparing the first sensing data and the second sensing data to determine whether a voltage level of the power supply voltage is lower than the reference voltage, and performing a core control operation to lower a channel potential of a selected NAND cell string when the voltage level of the power supply voltage is lower than the reference voltage.

### BRIEF DESCRIPTION OF THE FIGURES

The above and other objects and features of the present disclosure will become more apparent by describing in detail example embodiments thereof with reference to the accompanying drawings.

FIG. 1 is a block diagram showing a non-volatile memory device according to embodiments of the present disclosure.

FIG. 2 is a circuit diagram showing an example structure of a memory block included in the cell array of FIG. 1.

FIG. 3 is a block diagram showing the configuration of a cell array, a page buffer circuit, and a low-voltage manager according to embodiments of the present disclosure.

FIG. 4 is a graph showing the criteria for determining a low voltage state according to the level of the power supply voltage according to embodiments of the present disclosure.

FIG. 5 is a circuit diagram showing the configuration of one of the page buffers of FIG. 3.

FIG. 6 is a diagram illustrating the structures of a precharge level generator and a sensing latch for precharging and sensing of a sensing node.

FIG. 7 is a circuit diagram showing an example configuration of the divided power supply voltage generator of FIG. 6.

FIG. 8 is a graph showing the change in the bit line clamp signal according to the level of the power supply voltage in the precharge level generator of FIG. 6.

FIG. 9 is a graph showing the distribution of trip levels in the first sensing mode and second sensing mode of the page buffer circuit according to embodiments of the present disclosure.

FIG. 10 is a timing diagram showing core control operation according to embodiments of the present disclosure.

FIG. 11 is a flowchart showing the power supply voltage level detection and core control operation according to embodiments of the present disclosure.

FIG. 12 is a timing diagram showing core control operation according to further embodiments of the present disclosure.

FIG. 13 is a flowchart showing the power supply voltage level detection and core control operation according to further embodiments of the present disclosure.

### DETAILED DESCRIPTION

It is to be understood that both the foregoing general description and the following detailed description are examples, and it is to be considered that an additional description of the present disclosure is provided. Reference signs are indicated in detail in embodiments of the present disclosure, examples of which are indicated in the reference drawings. Wherever possible, the same reference numbers are used in the description and drawings to refer to the same or like parts.

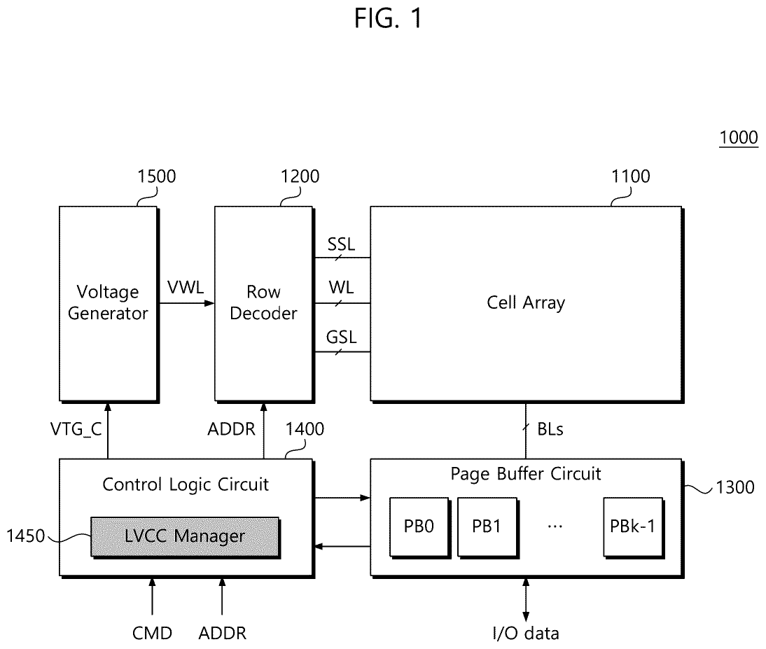

FIG. 1 is a block diagram showing a non-volatile memory device according to embodiments of the present disclosure. Referring to FIG. 1, the non-volatile memory device 1000 may include a cell array 1100, a row decoder 1200, a page buffer circuit 1300, a control logic circuit 1400, and a voltage generator 1500.

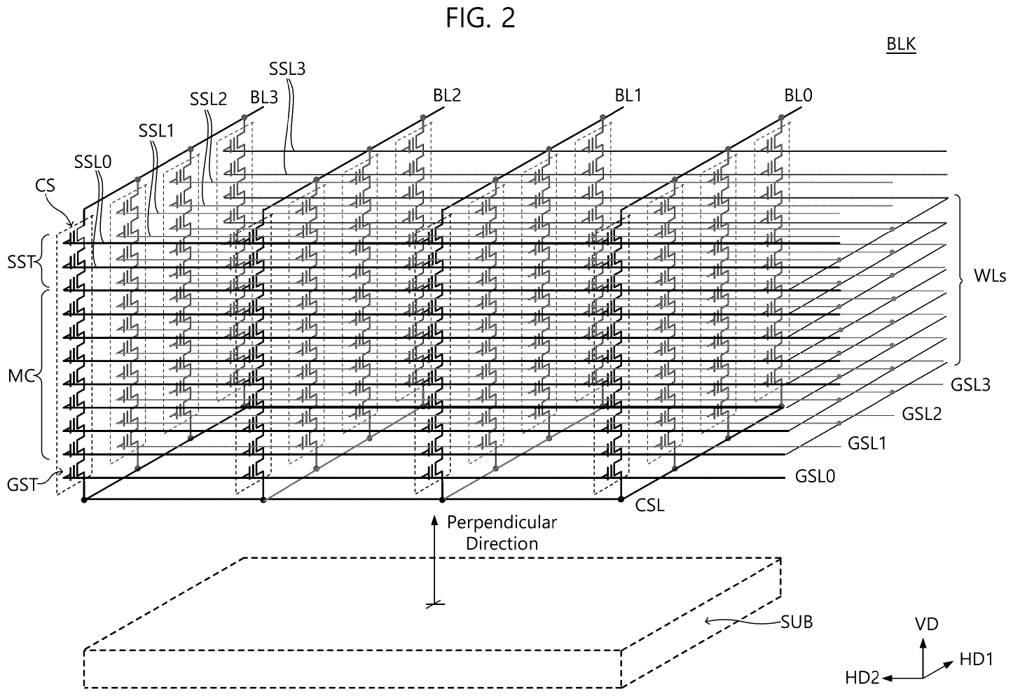

The cell array 1100 may be connected to the row decoder 1200 through word lines WL and/or select lines SSL and GSL. The cell array 1100 may be connected to the page buffer circuit 1300 through bit lines BLs. The cell array 1100 may include a plurality of NAND cell strings. A channel of each cell string may be formed in a direction perpendicular to the substrate (e.g., see the substrate SUB in FIG. 2). The cell array 1100 may include a plurality of memory cells forming a cell string. A plurality of memory cells can be programmed, erased, and sensed by voltage provided to bit lines BLs or word lines WL. Program operations can be performed on a page-by-page basis, and erase operations can be performed on a block-by-block basis.

In embodiments of the present disclosure, the cell array 1100 may be provided as a three-dimensional memory array. A three-dimensional memory array may be formed monolithically (e.g., an integrated unit) in one or more physical levels of an array of memory cells with an active area disposed over a silicon substrate and circuitry associated with the operation of the memory cells. Circuitry associated with the operation of the memory cells may be located within or on the substrate. The term monolithic means that the layers of each level of the three-dimensional array are deposited directly on top of the layers of lower levels of the three-dimensional array.

In embodiments of the present disclosure, a three-dimensional memory array may have vertical orientation and includes vertical NAND strings where at least one memory cell is located above another memory cell. At least one memory cell may include a charge trap layer. Each vertical NAND string may include at least one select transistor located above the memory cells. At least one selection transistor may have the same structure as the memory cells and may be formed monolithically (e.g., may be integrated) with the memory cells.

The row decoder 1200 may select one of the memory blocks of the cell array 1100 in response to the address ADDR. For example, the row decoder 1200 may select a row of the cell array 1100 in response to the address ADDR. The row decoder 1200 may select one of the word lines WL of the selected memory block in response to the address ADDR. The row decoder 1200 may deliver a word line voltage VWL corresponding to the operation mode to the word line of the selected memory block. During a program operation, the row decoder 1200 may transmit the program voltage and verification voltage to the selected word line and the write pass voltage (Vpass) to the unselected word line(s). During a data read operation, the row decoder 1200 may deliver a read voltage to the selected word line and a read pass voltage (Vread) to the unselected word line(s).

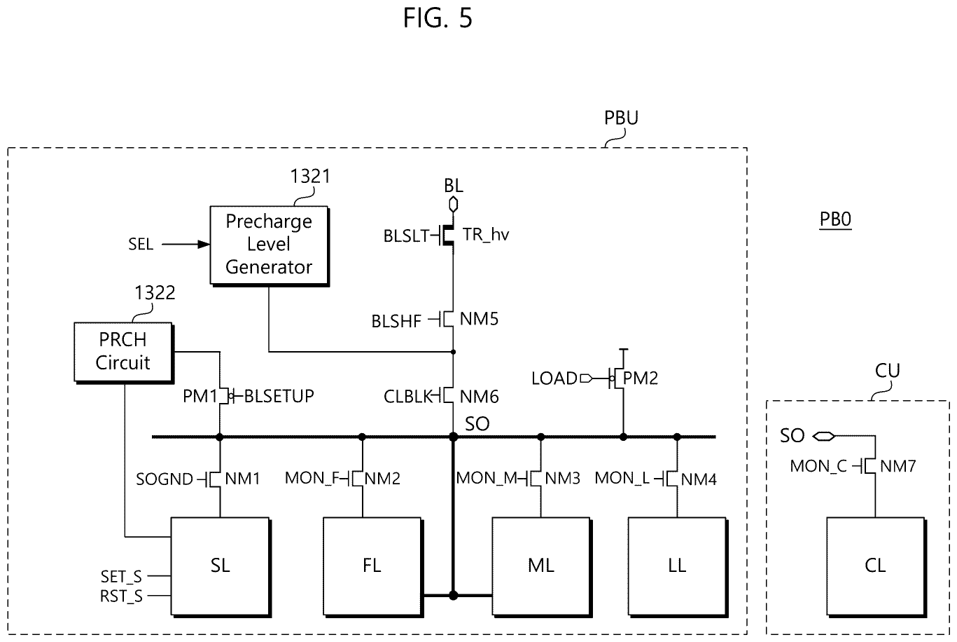

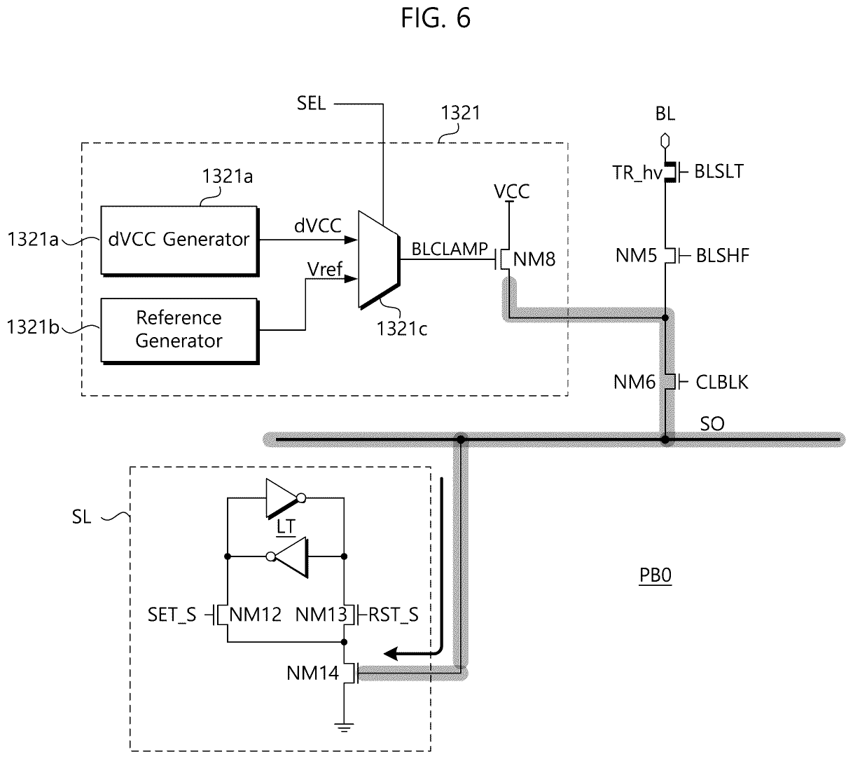

The page buffer circuit 1300 may operate as a write driver or a sense amplifier. During the program operation, the page buffer circuit 1300 may transfer a bit line voltage corresponding to data to be programmed to the bit lines BLs of the cell array 1100. During the data read operation or a verify read operation, the page buffer circuit 1300 may detect data stored in the selected memory cell through bit lines BLs. Here, the data read operation refers to a general read operation that senses data stored in the cell array 1100 according to an external request. Additionally, the operation of sensing whether data has been normally written to the selected memory cell during the program operation will be referred to as the verify read operation. The page buffer circuit 1300 may precharge a sensing node SO (e.g., see FIGS. 5 and 6) according to data sensed through bit lines BLs in a data read operation and the verify read operation. The page buffer circuit 1300 may latch the read data according to the level of the precharged sensing node SO.

The page buffer circuit 1300 may detect a decrease in the power supply voltage (VCC) using the precharge level of the sensing node SO. Hereinafter, the case where the power supply voltage (VCC) drops below the reference voltage (Vref) will be referred to as a low voltage state (Low_VCC). The page buffer circuit 1300 may perform precharge and sensing of the sensing node SO to reflect the level of the current power supply voltage (VCC) under the control of the control logic circuit 1400. The control logic circuit 1400 may determine whether the low voltage state (Low_VCC) exists using a method such as fail bit count from the sensed results. If the power supply voltage (VCC) of the nonvolatile memory device 1000 corresponds to the low voltage state (Low_VCC), a hot-carrier-injection (HCI) may occur in the cell string. The control logic circuit 1400 may perform a core control operation to block the hot-carrier-injection (HCI) caused by the low voltage state (Low_VCC). Here, the core control operation refers to an operation to block the hot-carrier-injection (HCI) phenomenon by discharging the boosted channel charge by controlling the level of the word line voltage or bit line of the selected memory block. Specific examples of core control operations will be described in greater detail through the drawings described later.

The control logic circuit 1400 may control the page buffer circuit 1300, the row decoder 1200, and the voltage generator 1500 in response to a command CMD transmitted from the outside (e.g., transmitted from an external source). The control logic circuit 1400 can control the voltage generator 1500, the page buffer circuit 1300, and the row decoder 1200 to perform program, read, and erase operations on the selected memory cell according to the command CMD. The control logic circuit 1400 may deliver an address ADDR to the row decoder 1200 and may provide a voltage control signal VTG_C to the voltage generator 1500.

In particular, the control logic circuit 1400 may include a low voltage manager 1450. As used herein, the control logic circuit 1400 and the low voltage manager 1450 may also be referred to as a control circuit. The low voltage manager 1450 may control the page buffer circuit 1300 to detect the low voltage state (Low_VCC), and performs the core control operation when the low voltage state (Low_VCC) is detected. The low voltage manager 1450 may control the page buffer circuit 1300 to precharge and sense the sensing node SO according to the level of the power supply voltage (VCC). The low voltage manager 1450 may determine the low voltage state (Low_VCC) by referring to the sensing result of the page buffer circuit 1300. When in the low voltage state (Low_VCC), the low voltage manager 1450 may control the row decoder 1200 or the page buffer circuit 1300 to perform the core control operation.

The voltage generator 1500 may generate various types of word line voltages VWL to be supplied to each word line under the control of the control logic circuit 1400 and to the bulk (e.g., well area) where the memory cells are formed. Word line voltages VWL to be supplied to each word line may include program voltage, write pass voltage (Vpass), read voltage (Vrd), and read pass voltage (Vread).

Although not shown, the non-volatile memory device 1000 may further include components such as an input/output buffer (I/O Buffer), a digital mass bit counter (DMBC), and/or a fail bit counter. As described above, the nonvolatile memory device 1000 may detect a low voltage state (Low_VCC) using precharge and sensing of the sensing node SO of the page buffer circuit 1300. Additionally, when the nonvolatile memory device 1000 is in the low voltage state (Low_VCC), it may perform the core control operation to block changes in the threshold voltage of memory cells. Accordingly, the nonvolatile memory device 1000 can ensure data reliability in the low voltage state without using a method of increasing the driving strength of the charge pump, according to embodiments of the present disclosure.

FIG. 2 is a circuit diagram showing an example structure of a memory block included in the cell array of FIG. 1. Referring to FIG. 2, cell strings CS may be formed between the bit lines BL0, BL1, BL2, and BL3 and the common source line CSL to form the memory block BLK. As shown in FIG. 2, first and second horizontal directions HD1 and HD2 may intersect each other and may be substantially parallel to an upper surface of a substrate SUB. A vertical direction VD may intersect the first and second horizontal directions HD1 and HD2 and may be substantially perpendicular to the upper surface of the substrate SUB.

A plurality of cell strings CS may be formed between each of the bit lines BL0, BL1, BL2, and BL3 and the common source line CSL. The string select transistor SST of the cell strings CS may be connected to the corresponding bit line BL. The ground select transistor GST of the cell strings CS may be connected to the common source line CSL. Memory cells MC are provided between the string select transistor SST and the ground select transistor GST of the cell string CS.

Each of the cell strings CS may include the ground select transistor GST. Ground selection transistors included in the cell strings CS may be controlled by the ground selection line GSL (GSL0, GSL1, GSL2, or GSL3). In other embodiments, although not shown, cell strings corresponding to each row may be controlled by different ground selection lines.

Above, the circuit structure of memory cells MC included in one memory block BLK was briefly described. However, the circuit structure of the illustrated memory block is only a simplified structure for convenience of explanation, and the actual memory block is not limited to the illustrated example. That is, it will be understood that one physical block may include more semiconductor layers, bit lines BLs (BL0, BL1, BL2, and BL3), and string select lines SSLs (SSL0, SSL1, SSL2, and SSL3).

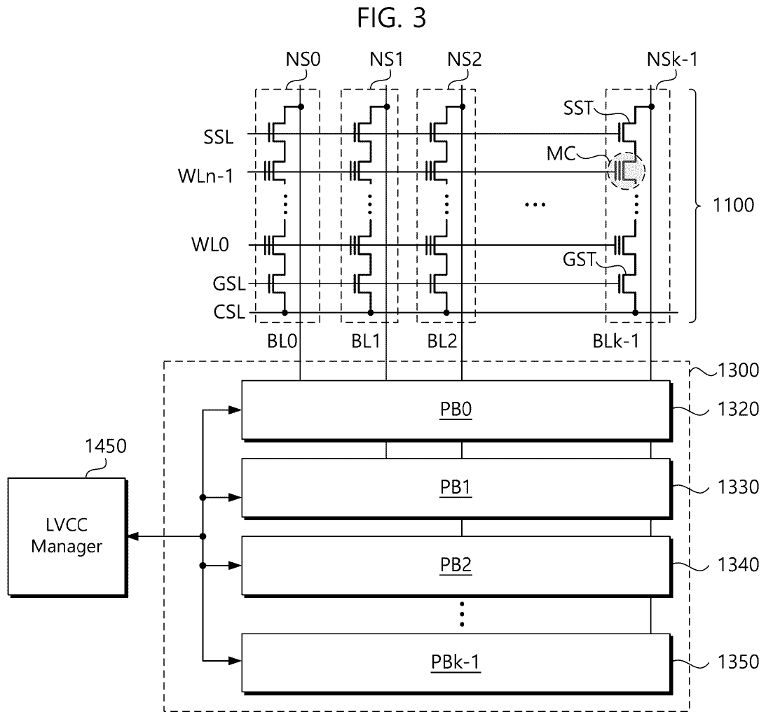

FIG. 3 is a block diagram showing the configuration of a cell array, a page buffer circuit, and a low-voltage manager according to embodiments of the present disclosure. Referring to FIG. 3, the low voltage manager 1450 may detect a low voltage state (Low_VCC) of the page buffer circuit 1300 and perform core control operations accordingly.

Each of the plurality of NAND cell strings NSO to NSk-1 may include a ground selection transistor GST connected to the ground selection line GSL. Each of the NAND cell strings NSO to NSk-1 may include a plurality of memory cells MC connected to a plurality of word lines WL0 to WLn-1, and a string selection transistor SST connected to a string selection line SSL. The ground select transistor GST, memory cells MC, and string select transistor SST may be connected to each other in series.

The page buffer circuit 1300 may include a plurality of page buffers PB0 to PBk-1. The first page buffer PB0 may be connected to the first NAND cell string NSO through the first bit line BL0, and the k-th page buffer PBk-1 may be connected to the kth NAND cell string NSk-1 through the k-th bit line BLk-1. Here, ‘k’ is a positive integer. For example, ‘k’ may be 8, and the page buffer circuit 1300 may have a structure in which 8 page buffers (PB0 to PB7) are arranged in a row, but the present disclosure is not limited thereto.

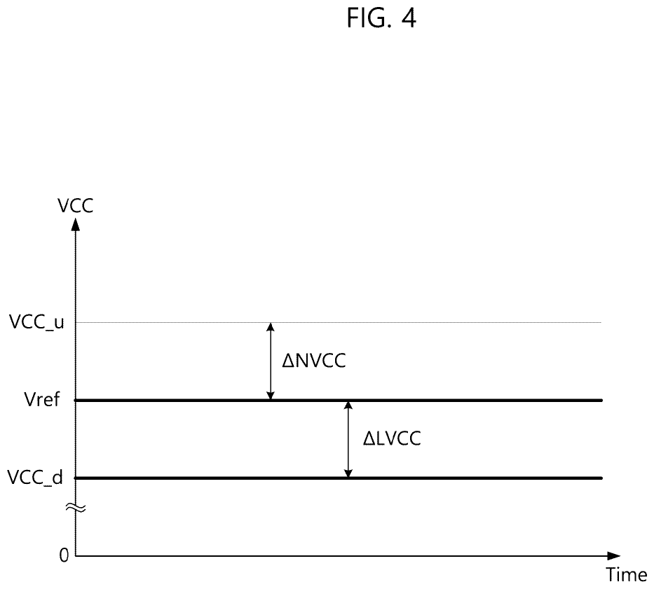

Each of the plurality of page buffers PB0 to PBk-1 can program or sense data in selected memory cells. For example, the plurality of page buffers PB0 to PBk-1 may sense memory cells of a selected row in the cell array 1100 (e.g., selected by the row decoder 1200 in FIG. 1) through the bit lines BL0 to BLk-1. In particular, each of the plurality of page buffers PB0 to PBk-1 may precharge and sense the sensing node SO to detect whether the power supply voltage (VCC) is in a low voltage state (Low_VCC) (e.g., see FIGS. 5 and 6). For example, each of the plurality of page buffers PB0 to PBk-1 may perform precharge and sensing operations on the sensing node SO to detect the state of the power supply voltage (VCC). Each of the plurality of page buffers PB0 to PBk-1 may precharge the sensing node SO using the reference voltage (Vref) and then latch it. Further, each of the plurality of page buffers PB0 to PBk-1 may use the power supply voltage (VCC) to precharge the sensing node SO and then latch it. Thereafter, the low voltage manager 1450 may compare the latch data of the reference voltage (Vref) and the latch data of the power supply voltage (VCC) latched in the plurality of page buffers PB0 to PBk-1. The low voltage manager 1450 may determine whether the level of the power supply voltage (VCC) is in a low voltage state (Low_VCC) based on the comparison result. To compare the latch data of the reference voltage (Vref) and the latch data of the power voltage (VCC), the low voltage manager 1450 may use a fail bit counter (FBC) or a digital mass bit counter (DMBC). The configuration of each of the page buffers PB0 to PBk-1 will be explained in more detail with reference to FIG. 4 described later.

The low voltage manager 1450 may control each of the page buffers PB0 to PBk-1 of the page buffer circuit 1300 to detect a low voltage state (Low_VCC) of the power supply voltage (VCC). When the level of the detected power supply voltage (VCC) corresponds to a low voltage state (Low_VCC), the low voltage manager 1450 may perform a core control operation to block changes in the threshold voltage distribution of memory cells. During the read operation, the low voltage manager 1450 may perform precharge and sensing operations on the sensing nodes SO of each of the page buffers PB0 to PBk-1 using the reference voltage (Vref) and the power supply voltage (VCC), respectively. The low voltage manager 1450 may use the results of the precharge and sensing operations to determine whether the current power supply voltage (VCC) corresponds to the low voltage state (Low_VCC).

The low voltage manager 1450 and the page buffer circuit 1300 may determine the state of the power supply voltage (VCC) by detecting the precharge level of the sensing node SO. When the power supply voltage (VCC) corresponds to a low voltage state (Low_VCC), the low-voltage manager 1450 can perform the core control operation to block the hot-carrier-injection (HCI) due to low voltage in the cell string. The core control operation may be performed, for example, by maintaining the word line voltage at the read pass voltage (Vread) or extending the page buffer initialization time during the page buffer initialization operation.

FIG. 4 is a graph showing the criteria for determining a low voltage state (Low_VCC) according to the level of the power supply voltage VCC according to embodiments of the present disclosure. Referring to FIG. 4, the level of the power supply voltage VCC supplied to the non-volatile memory device 1000 may be divided into a normal voltage range ΔNVCC and a low voltage range ΔLVCC centered on the reference voltage Vref.

When the level of the externally provided power supply voltage VCC is higher than the reference voltage Vref and below the upper limit voltage VCC_u, it is referred to as the normal voltage range ΔNVCC. When the level of the power supply voltage VCC corresponds to the normal voltage range ΔNVCC, the nonvolatile memory device 1000 can perform normal read, write, and erase operations. The power supply voltage VCC in the normal voltage range ΔNVCC is provided at a level to ensure normal operating conditions in the product specifications of the non-volatile memory device 1000.

On the other hand, when the level of the power supply voltage VCC corresponds to the low voltage range ΔLVCC lower than the reference voltage Vref, normal read, write, and erase operations of the nonvolatile memory device 1000 may not be guaranteed. Hereinafter, the case where the level of the power supply voltage VCC corresponds to the low voltage range ΔLVCC will be referred to as a low voltage state (Low_VCC). In particular, when memory cells are read at a power supply voltage VCC in the low voltage range ΔLVCC, hot-carrier-injection (HCI) may occur in a channel of a cell string. The hot-carrier-injection (HCI) that can occur in a low voltage state (Low_VCC) affects the threshold voltage distribution of memory cells. Accordingly, data reliability of the nonvolatile memory device 1000 may be degraded due to hot-carrier-injection (HCI) caused by a low voltage state (Low_VCC).

When the level of the power supply voltage VCC is lower than the low voltage range ΔLVCC, that is, when the level of the power supply voltage VCC is lower than the lower limit voltage VCC_d, the trim or reset operation on the non-volatile memory device 1000 may be performed.

The page buffer circuit 1300 and the low voltage manager 1450 may detect whether a low voltage state (Low_VCC) exists by performing sensing after precharging the sensing node SO according to the level of the power supply voltage VCC (e.g., see FIGS. 1, 3, 5 and 6). Through sensing of the sensing node SO, the level of the power supply voltage VCC can be detected using a digital mass bit counter (DMBC) or a fail bit counter (FBC). Accordingly, the nonvolatile memory device 1000 according to embodiments of the present disclosure can detect the low voltage state (Low_VCC) of the power supply voltage VCC with high accuracy while minimizing additional components.

FIG. 5 is a circuit diagram showing the configuration of one of the page buffers of FIG. 3. Referring to FIG. 5, the page buffer PB0 may include a page buffer unit PBU and a cache unit CU. The cache unit CU may include a cache latch CL, and the cache latch CL may be connected to the data input/output line, so the cache unit CU may be placed adjacent to the data input/output line. For example, a seventh transistor NM7 may connect the cache latch CL and the sensing node SO in response to a cache monitoring signal MON_C. Accordingly, the page buffer unit PBU and the cache unit CU may be arranged to be spaced apart from each other, and the page buffer PB0 may have a separation structure of the page buffer unit PBU and the cache unit CU.

The page buffer unit PBU may include a bit line selection transistor TR_hv connected to the bit line BL and driven by the bit line select signal BLSLT. The bit line selection transistor TR_hv may be implemented as a high voltage transistor, and accordingly, the bit line selection transistor TR_hv may be disposed in a high voltage region.

The page buffer unit PBU may include a sensing latch SL, a forcing latch FL, a most significant bit (MSB) latch ML, and a least significant bit (LSB) latch LL. During the program operation, data to be programmed may be stored in the MSB latch ML, LSB latch LL, and cache latch CL. In addition, the page buffer unit PBU may include a precharge level generator 1321 and a precharge circuit 1322. The precharge level generator 1321 may generate a precharge voltage of the sensing node SO to detect a low voltage state (Low_VCC) according to embodiments of the present disclosure. The precharge level generator 1321 may generate a bit line clamp signal BLCLAMP (e.g., see FIG. 6) at a level (e.g., a voltage level) corresponding to the reference voltage (Vref) or the current power supply voltage (VCC) according to the selection signal SEL provided from the low voltage manager 1450 (e.g., see FIGS. 1 and 3). The precharge level generator 1321 may precharge the sensing node SO using the bit line clamp signal BLCLAMP that reflects the level of the reference voltage (Vref) and the current power supply voltage (VCC).

The sensing latch SL may store the data stored in the memory cell or the sensing result of the threshold voltage of the memory cell during a read or program verify operation. Additionally, the sensing latch SL may be used to apply a program bit line voltage or a program inhibit voltage to the bit line BL during a program operation. The forcing latch FL may be used as a bit line bias means to improve threshold voltage distribution during program operation. The MSB latch ML, LSB latch LL, and cache latch CL may be used to store externally input data during program operation.

In particular, the sensing latch SL may latch the sensing node SO precharged by the precharge level generator 1321 according to a preset trip level. First, the precharge level generator 1321 may precharge the sensing node SO by the reference voltage (Vref). Then, the sensing latch SL may perform first sensing (i.e., a first sensing operation) to latch data according to the level (e.g., the voltage level) of the precharged sensing node SO. Next, the precharge level generator 1321 may precharge the sensing node SO using the power supply voltage (VCC). Then, the sensing latch SL may perform second sensing (i.e., a second sensing operation) to latch data according to the level (e.g., the voltage level) of the precharged sensing node SO. Afterwards, the results of two sensing operations performed by the sensing latch SL are compared. For example, the voltage level of the sensing node SO when precharged with the reference voltage (Vref) may be compared with the voltage level of the sensing node SO when precharged with the power supply voltage (VCC). Depending on the comparison result, it may be determined whether the power supply voltage (VCC) is in a low voltage state (Low_VCC).

The page buffer unit PBU may include a precharge circuit 1322 that can control a precharge operation for the bit line BL or the sensing node SO. The page buffer unit PBU may further include a transistor PM1 driven by a bit line setup signal BLSETUP.

The page buffer unit PBU may include first to fourth transistors NM1 to NM4. The first transistor NM1 may connect the sensing latch SL and the sensing node SO in response to the ground control signal SOGND. The second transistor NM2 may connect the forcing latch FL and the sensing node SO in response to the forcing monitoring signal MON_F. The third transistor NM3 may connect the MSB latch ML and the sensing node SO in response to the MSB monitoring signal MON_M. The fourth transistor NM4 may connect the LSB latch LL and the sensing node SO in response to the LSB monitoring signal MON_L.

The page buffer unit PBU may further include fifth and sixth transistors NM5 and NM6 connected in series between the bit line selection transistor TR_hv and the sensing node SO. The fifth transistor NM5 may be driven by the bit line shut-off signal BLSHF, and the sixth transistor NM6 may be driven by the bit line connection control signal CLBLK. Additionally, the page buffer unit PBU may further include a precharge transistor PM2. The precharge transistor PM2 is connected to the sensing node SO and may be driven by the load signal LOAD.

In the above, the first and second sensing (i.e., the first and second sensing operations) of the sensing node SO may be performed using the bit line clamp signal BLCLAMP, and the page buffer PB0 may be used to determine whether the low voltage state (Low_VCC) is present according to the results of the first and second sensing operations. Here, the configuration of one page buffer PB0 has been described as an example, but the remaining page buffers (PB1, . . . , PBk-1) may each have the same structure. That is, each of the page buffers PB1, . . . , PBk-1 shown in FIG. 3 may have the same structure as the page buffer PB0.

FIG. 6 is a diagram illustrating the structures of a precharge level generator and a sensing latch for precharging and sensing of a sensing node. Referring to FIG. 6, the precharge level generator 1321 may precharge the sensing node SO with the reference voltage Vref and the divided power supply voltage dVCC using the bit line clamp signal BLCLAMP. The sensing latch SL may latch the precharged sensing node SO with data through first sensing and second sensing (i.e., first and second sensing operations).

The precharge level generator 1321 may include a divided voltage generator 1321a, a reference voltage generator 1321b, a selection circuit 1321c, and an eighth transistor NM8. The divided voltage generator 1321a may divide the power supply voltage VCC and change it to a level for substantially precharging the sensing node SO. The reference voltage generator 1321b may generate the reference voltage Vref at a fixed level despite changes in the level of the power supply voltage VCC, process changes, or temperature changes. For example, the reference voltage generator 1321b may be implemented using a bandgap reference voltage generator circuit. The selection circuit 1321c may select either the divided power supply voltage dVCC or the reference voltage Vref in response to the selection signal SEL provided from the low voltage manager 1450 (e.g., see FIGS. 1 and 3) and output it as a bit line clamp signal BLCLAMP. That is, the selection circuit 1321c may select the divided power supply voltage dVCC or the reference voltage Vref in response to the selection signal SEL provided from the low voltage manager 1450 to generate the bit line clamp signal BLCLAMP. The eighth transistor NM8 may charge the sensing node SO according to the level of the bit line clamp signal BLCLAMP.

In order to detect whether the power supply voltage VCC is in a low voltage state (Low_VCC), the page buffer PB0 may perform first sensing and second sensing (i.e., first sensing and second sensing operations). For first sensing, the precharge level generator 1321 may precharge the sensing node SO using the reference voltage Vref. For second sensing, the precharge level generator 1321 may precharge the sensing node SO using the divided power supply voltage dVCC.

The sensing latch SL may latch data according to the level of the sensing node SO precharged by the reference voltage Vref for the first sensing. That is, the NMOS transistor NM14 provided for grounding the latch LT may be turned on or off depending on the level of the sensing node SO. Then, the latch LT may be tripped when the reset signal RST_S transitions to high level. That is, the latch LT may trip or maintain the current state depending on the level of the reference voltage Vref. At this time, the latched data can be moved to the data latches ML and LL or the cache latch CL (see FIG. 5). This first sensing may occur in each of the page buffers PB0, PB1, . . . , PBk-1 (e.g., see FIGS. 1 and 3). The sensing latch SL may be controlled by the set signal SET_S and the reset signal RST_S.

The sensing latch SL may latch the level of the sensing node SO precharged by the divided power supply voltage dVCC as data for second sensing. That is, the NMOS transistor NM14 provided for grounding the latch LT may be turned on according to the level of the sensing node SO precharged by the divided power supply voltage dVCC. When the reset signal RST_S transitions to high level, the latch LT may trip to ‘0’ or ‘1’. That is, the latch LT may trip or maintain the status quo depending on the level of the divided power supply voltage dVCC. At this time, the latched data can be moved to the data latches ML and LL or the cache latch CL (see FIG. 5). This second sensing occurs in each of the page buffers PB0, PB1, . . . , PBk-1 (e.g., see FIGS. 1 and 3).

The result data of the first sensing and the second sensing performed in each of the page buffers PB0, PB1, . . . , PBk-1 may be compared with each other. For example, the number of data bits switched may be counted using a fail bit count or digital mass bit count method. The level status of the divided power supply voltage dVCC may be determined according to the count result data. Therefore, a standard can be provided to determine whether the current power supply voltage VCC level is in a low voltage state (Low_VCC).

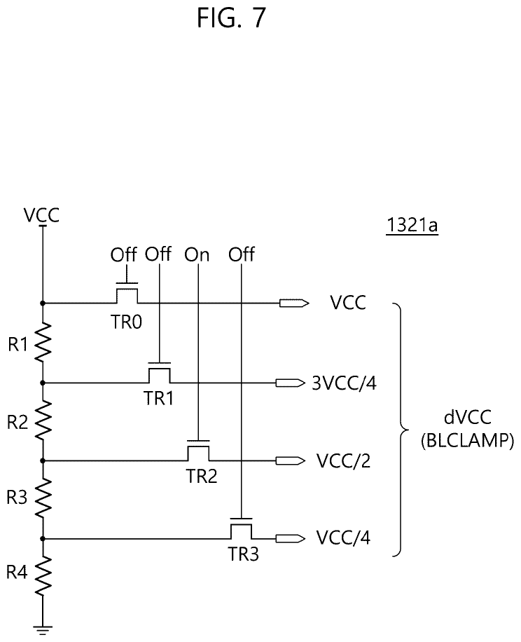

FIG. 7 is a circuit diagram showing an example configuration of the divided voltage generator of FIG. 6. Referring to FIG. 7, the divided voltage generator 1321a may include a plurality of resistors R1, R2, R3, and R4 connected in series between the power supply voltage VCC and ground and selection transistors TR0, TR1, TR2, and TR3 for selecting the divided voltage. For example, each of the plurality of resistors R1, R2, R3, and R4 may be formed with the same resistance value. The divided voltage generator 1321a may be used when the relatively high power supply voltage VCC needs to be reduced to a level for precharging the sensing node SO. For example, the power supply voltage VCC may be divided using the divided voltage generator 1321a (e.g., a voltage divider) to generate the divided power supply voltage dVCC, and the bit line clamp signal BLCLAMP may correspond to the divided power supply voltage dVCC. In other embodiments, the power supply voltage VCC may not be divided but may be directly provided as the bit line clamp signal BLCLAMP.

When a half-leveled power supply voltage VCC/2 is used as the divided power supply voltage dVCC, the selection transistor TR2 is turned on, and the remaining selection transistors TR0, TR1, and TR3 are turned off. Then, a half-leveled power supply voltage VCC/2 can be selected and provided as the bit line clamp signal BLCLAMP. On the other hand, in order to directly transfer the power voltage VCC to the bit line clamp signal BLCLAMP without dividing it, the selection transistor TR0 is turned on, and the remaining selection transistors TR1, TR2, and TR3 are turned off. Then, the voltage VCC can be provided as the bit line clamp signal BLCLAMP without reducing the level of the power supply voltage VCC.

Here, the divided voltage generator 1321a is provided as a means to precharge the sensing node SO (see FIGS. 5 and 6) by reflecting the level of the current power supply voltage VCC. A method of precharging the sensing node SO by changing the level of the power supply voltage VCC using a voltage drop method has been described according to embodiments, but the present disclosure is not limited thereto.

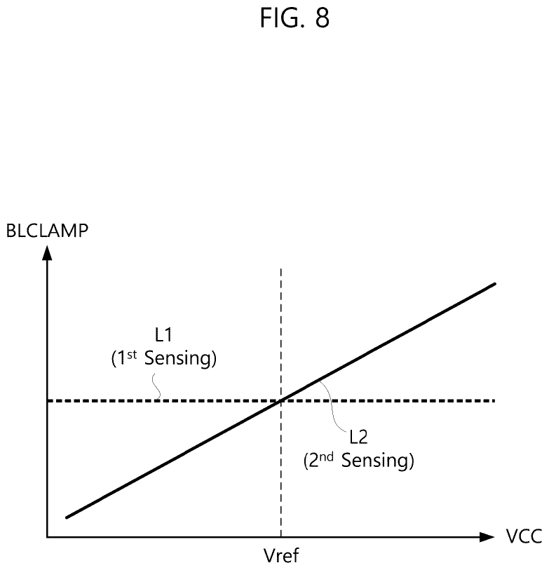

FIG. 8 is a graph showing the change in the bit line clamp signal according to the level of the power supply voltage VCC in the precharge level generator of FIG. 6. Referring to FIG. 8, the precharge level generator 1321 (see FIG. 6) may generate a bit line clamp signal BLCLAMP corresponding to the reference voltage Vref and the divided power supply voltage dVCC in the first sensing mode and the second sensing mode, respectively.

In the first sensing mode (i.e., the first sensing operation), the precharge level generator 1321 may select the reference voltage Vref generated from the reference voltage generator 1321b and provide it as the bit line clamp signal BLCLAMP. Using a bandgap reference voltage generation circuit, the reference voltage generator 1321b may generate the reference voltage Vref at a constant level (e.g., a constant voltage level) without being affected by the operating environment such as the level of the power supply voltage VCC, temperature, or process changes. Therefore, in the first sensing mode, the bit line clamp signal BLCLAMP generated to precharge the sensing node SO may be transmitted in the same form as the first line L1 parallel to the power supply voltage VCC axis.

In the second sensing mode (i.e., the second sensing operation), the precharge level generator 1321 may select the divided power supply voltage dVCC generated from the divided voltage generator 1321a and provide it as the bit line clamp signal BLCLAMP. Then, the bit line clamp signal BLCLAMP that well reflects the level of the current power supply voltage VCC may be provided in the second sensing mode. That is, the bit line clamp signal BLCLAMP may have a straight line like the second line L2 with a constant slope proportional to the power supply voltage VCC.

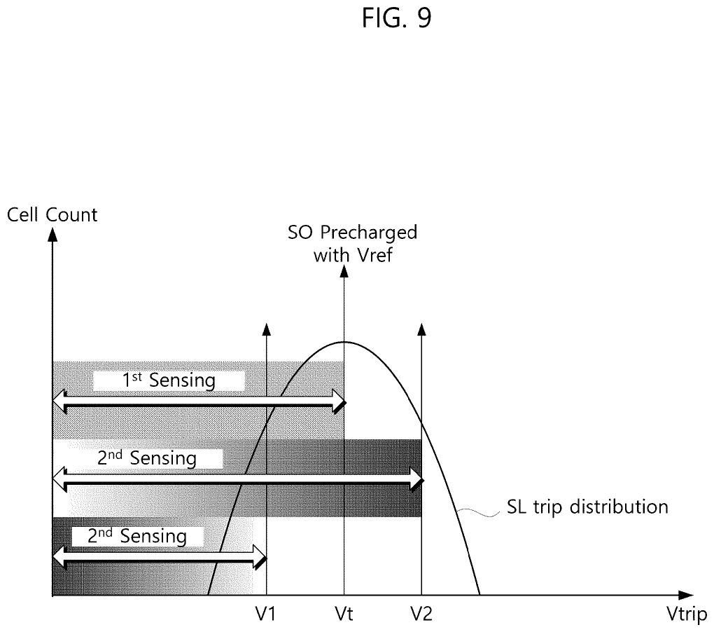

FIG. 9 is a graph showing the distribution of trip levels in a first sensing mode and second sensing mode of the page buffer circuit according to embodiments of the present disclosure. Referring to FIG. 9, the distribution of the trip voltage Vtrip according to the precharged voltage at the sensing node SO of each of the page buffers PB0, PB1, . . . , PBk-1 is shown.

The trip voltage Vtrip of the sensing latch SL of each sensing node SO of the page buffers PB0, PB1, . . . , PBk-1 may be expressed as the distribution shown. That is, when precharging the sensing node SO with the reference voltage Vref, the sensing latch SL of each of the page buffers PB0, PB1, . . . , PBk-1 can be tripped at the trip voltage Vt located at the center of the trip distribution.

In the first sensing mode (i.e., the first sensing operation), the sensing node SO is precharged using the bit line clamp signal BLCLAMP corresponding to the reference voltage Vref. Then, the latch operation is performed on the sensing nodes SO of each of the precharged page buffers PB0, PB1, . . . , PBk-1 using the reference voltage Vref. At this time, the first data sensed by the trip voltage Vt of the sensing latch SL is temporarily stored for comparison with the second sensing result.

In the subsequent second sensing mode (i.e., the second sensing operation), the sensing node SO is precharged by the bit line clamp signal BLCLAMP corresponding to the current state of the power supply voltage (VCC). If the level of the current power supply voltage (VCC) is lower than the reference voltage Vref, the sensing node SO is precharged to a level lower than the reference voltage Vref. On the other hand, when the level of the current power supply voltage (VCC) is equal to or higher than the reference voltage Vref, the sensing node SO is precharged to a level that is equal to or higher than the reference voltage Vref.

When counting the bit conversion (0->1 or 1->0) of the latched data as a result of the first sensing and the second sensing (i.e., the first sensing and the second sensing operations), it is possible to identify the relative size of the current power supply voltage (VCC) to the reference voltage Vref. In addition, it can be determined whether the level of the current power supply voltage (VCC) falls within the low voltage range (ΔLVCC) from the results of the first sensing and the second sensing (see FIG. 4).

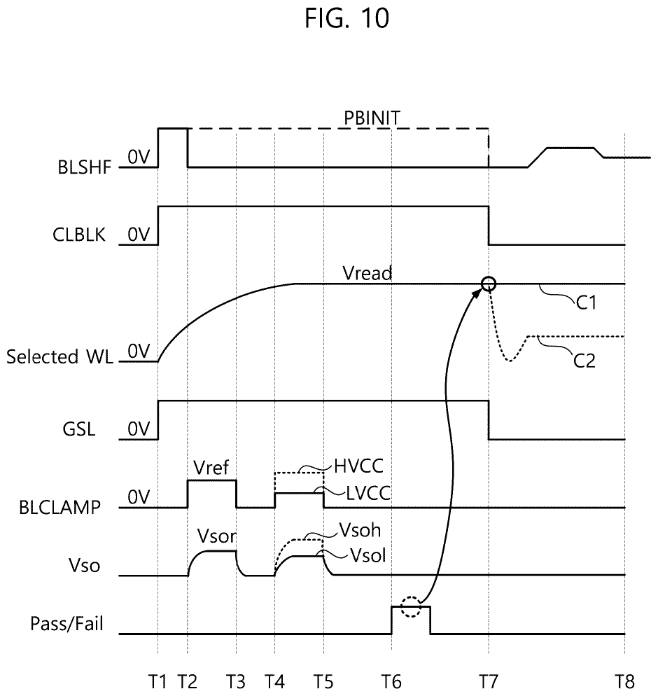

FIG. 10 is a timing diagram showing core control operation according to embodiments of the present disclosure. Referring to FIG. 10, in the page buffer initialization period PBINIT, whether the power supply voltage (VCC) is in a low voltage state (Low_VCC) can be detected through first sensing and second sensing. And when a low voltage state (Low_VCC) is detected, the hot-carrier-injection (HCI) can be blocked by extending the pre-pulse section of the selected word line WL performed in the page buffer initialization period PBINIT.

Referring to FIGS. 5, 6, and 10, at time T1, the page buffer initialization period PBINIT for a read operation begins. To initialize the page buffer PB0, the bit line shut-off signal BLSHF and the bit line connection control signal CLBLK transition to high level ‘H’. Then, the fifth and sixth transistors NM5 and NM6 connected in series between the bit line selection transistor TR_hv and the sensing node SO will be turned on. In addition, a read pass voltage Vread to remove the channel charge of the selected NAND cell string begins to be provided to the selected word line WL. Accordingly, the voltage of the selected word line WL begins to rise. At this time, the ground selection signal GSL of the selected NAND cell string is maintained at a high level, so that the charge of the boosted channel can be continuously discharged to ground.

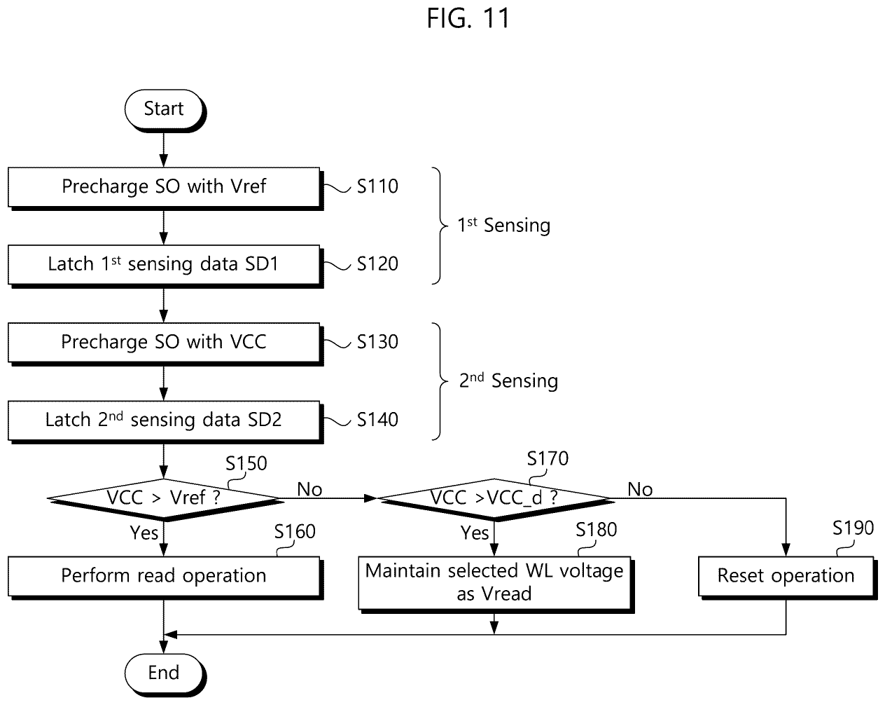

At time T2, the bit line shut-off signal BLSHF transitions to low level ‘L’ and the first sensing mode (i.e., the first sensing operation) begins. The bit line BL and the page buffer PB0 are blocked by the transition of the bit line shut-off signal BLSHF to the low level ‘L’. To execute the first sensing mode, the bit line clamp signal BLCLAMP is provided at the reference voltage Vref level. The sensing node SO (e.g., the sensing node voltage Vso) will be precharged to the reference sensing node voltage Vsor by the bit line clamp signal BLCLAMP. The sensing node SO precharged with the reference sensing node voltage Vsor is latched by the sensing latch SL. At this time, the latched data may be stored as first sensing data SD1 (e.g., see FIG. 11). The first sensing mode ends at time T3.

At time T4, the second sensing mode (i.e., the second sensing operation) starts while the bit line shut-off signal BLSHF is maintained at the low level ‘L’. To execute the second sensing mode, the bit line clamp signal BLCLAMP is generated with a value corresponding to the level of the current power supply voltage VCC. For example, when the level of the current power supply voltage VCC is higher than the reference voltage Vref, the bit line clamp signal BLCLAMP may be generated at a first voltage HVCC level higher than the reference voltage Vref. On the other hand, when the level of the current power supply voltage VCC is lower than the reference voltage Vref, the bit line clamp signal BLCLAMP may be generated at a second voltage LVCC level that is lower than the reference voltage Vref.

In the second sensing mode, when the bit line clamp signal BLCLAMP is generated at the first voltage HVCC level, the sensing node SO (e.g., the sensing node voltage Vso) will be precharged with the first sensing node voltage Vsoh. On the other hand, when the bit line clamp signal BLCLAMP is generated at a relatively low second voltage LVCC level, the sensing node SO (e.g., the sensing node voltage Vso) will be precharged with the second sensing node voltage Vsol. The state of the sensing node SO precharged with the first sensing node voltage Vsoh or the second sensing node voltage Vsol is latched by the sensing latch SL. At this time, the latched data may be stored as second sensing data SD2 (e.g., see FIG. 11). The second sensing mode ends at T5.

At time T6, the state of the current power supply voltage VCC is determined by comparing the first sensing data SD1 and the second sensing data SD2. In other words, a pass/fail determination is made to determine whether the current level of the power supply voltage VCC corresponds to a low voltage state (Low_VCC). First sensing data SD1 is obtained as a result of the first sensing mode, which precharges and senses the sensing node SO using the bit line clamp signal BLCLAMP corresponding to the voltage level of the reference voltage Vref. And, as a result of the second sensing mode, which precharges and senses the sensing node SO using the bit line clamp signal BLCLAMP corresponding to the voltage level of the current power voltage VCC, second sensing data SD2 is obtained. The low voltage manager (1450, see FIGS. 1 and 3) determines whether the power supply voltage VCC is in a low voltage state (Low_VCC) by using the fail bit count (FBC) or digital mass bit count (DMBC) technique for the first sensing data SD1 and the second sensing data SD2. If the level of the current power supply voltage VCC corresponds to a low voltage state (Low_VCC), the low voltage manager 1450 may determine the page buffer initialization PBINIT as Fail. On the other hand, if the level of the current power supply voltage VCC does not correspond to the low voltage state (Low_VCC), the low voltage manager 1450 may determine the current power supply voltage VCC state as Pass.

At time T7, if the level of the current power supply voltage VCC corresponds to a low voltage state (Low_VCC), the low voltage manager 1450 maintains the read pass voltage Vread level without lowering the voltage of the selected word line WL. In other words, the low voltage manager 1450 may extend a time period (i.e., duration) for which the selected word line WL is maintained at the read pass voltage Vread level (e.g., during the page buffer initialization PBINIT period). The waveform of this selected word line WL voltage is shown in curve C1 as a solid line. In this case, the effect of increasing the time during which the boosted charge of the selected NAND cell string is discharged to the ground is provided. In other words, it is possible to effectively form a path to remove charge from the channel of the NAND cell string during the pre-pulse section of the read operation. Accordingly, the effect of reducing or preventing hot-carrier-injection (HCI) is provided. On the other hand, if the level of the current power supply voltage VCC corresponds to a normal state higher than the reference voltage Vref, the voltage of the selected word line WL may rise to the read voltage level after recovery. The waveform of this selected word line WL voltage is shown in curve C2 as a dotted line.

FIG. 11 is a flowchart showing the power supply voltage level detection and core control operation according to embodiments of the present disclosure. Referring to FIGS. 1, 3-6, 10, and 11, the nonvolatile memory device 1000 may identify whether a power supply voltage VCC is in a low voltage state (Low_VCC) by performing first sensing and second sensing (i.e., first sensing and second sensing operations) on a sensing node SO of a page buffer circuit 1300. In addition, the non-volatile memory device 1000 may perform a core control operation to reduce or prevent hot-carrier-injection (HCI) that may occur when the power supply voltage VCC is in a low voltage state (Low_VCC).

In step S110, the bit lines BL and the page buffers PB0, PB1, . . . , PBk-1 are electrically blocked by the transition of the bit line shut-off signal BLSHF to the low level ‘L’. To execute the first sensing mode, the reference voltage Vref is provided as the bit line clamp signal BLCLAMP. The sensing node SO is precharged by the bit line clamp signal BLCLAMP at the reference voltage Vref level. That is, the sensing nodes SO of the page buffers PB0, PB1, . . . , PBk-1 may be precharged based on the reference voltage Vref. For example, the bit line clamp signal BLCLAMP may be generated corresponding to the reference voltage Vref, and the sensing nodes SO of the page buffers PB0, PB1, . . . , PBk-1 may be precharged based on the bit line clamp signal BLCLAMP.

In step S120, the sensing node SO of each of the page buffers PB0, PB1, . . . , PBk-1 precharged by the reference voltage Vref is sensed and latched by the sensing latch SL. At this time, the latched data may be stored as first sensing data SD1. That is, the sensing nodes SO of the page buffers PB0, PB1, . . . , PBk-1 may be latched to obtain the first sensing data SD1. For example, the low voltage manager 1450 may control the page buffers PB0, PB1, . . . , PBk-1 to precharge and sense the sensing nodes SO based on the reference voltage Vref to obtain the first sensing data SD1. Steps S110 and S120 constitute the first sensing mode.

In step S130, to execute the second sensing mode, the bit line clamp signal BLCLAMP is generated with a value corresponding to the level of the current power supply voltage VCC. For example, when the level of the current power supply voltage VCC is higher than the reference voltage Vref, the bit line clamp signal BLCLAMP may be generated at a first voltage HVCC level higher than the reference voltage Vref. On the other hand, when the level of the current power supply voltage VCC is lower than the reference voltage Vref, the bit line clamp signal BLCLAMP may be generated at a second voltage LVCC level that is lower than the reference voltage Vref. The sensing node SO is precharged by the bit line clamp signal BLCLAMP corresponding to the level of the current power supply voltage VCC. That is, the sensing nodes SO of the page buffers PB0, PB1, . . . , PBk-1 may be precharged based on the power supply voltage VCC. For example, the bit line clamp signal BLCLAMP may be generated corresponding to the power supply voltage VCC (e.g., at the first voltage HVCC or the second voltage LVCC), and the sensing nodes SO of the page buffers PB0, PB1, . . . , PBk-1 may be precharged based on the bit line clamp signal BLCLAMP.

In step S140, data corresponding to the sensing node SO of each of the page buffers PB0, PB1, . . . , PBk-1 precharged by the bit line clamp signal BLCLAMP based on the level of the current power supply voltage VCC is latched into the sensing latch SL. At this time, the latched data may be stored as second sensing data SD2. That is, the sensing nodes SO of the page buffers PB0, PB1, . . . , PBk-1 may be latched to obtain the second sensing data SD2. For example, the low voltage manager 1450 may control the page buffers PB0, PB1, . . . , PBk-1 to precharge and sense the sensing nodes SO based on the power supply voltage VCC to obtain the second sensing data SD2. Steps S130 and S140 constitute a second sensing mode.

In step S150, the low voltage manager 1450 determines the state of the current power supply voltage VCC using the first sensing data SD1 and the second sensing data SD2. That is, the low voltage manager 1450 determines whether the level of the current power supply voltage VCC is higher than the reference voltage Vref (e.g., based on a comparison between the first sensing data SD1 and the second sensing data SD2). For example, the low voltage manager 1450 may perform a low voltage detection operation by comparing the first sensing data SD1 and the second sensing data SD2 to determine whether the voltage level of the power supply voltage VCC is lower than the reference voltage Vref. If it is determined that the level of the current power supply voltage VCC is higher than the reference voltage Vref (‘Yes’ direction), the operation moves to step S160. On the other hand, if it is determined that the level of the current power supply voltage VCC is not higher than the reference voltage Vref (‘No’ direction), the operation moves to step S170. For example, the low voltage manager 1450 may compare the first sensing data SD1 and the second sensing data SD2 using a fail bit count technique (e.g., a fail bit counter) or a digital mass bit count technique (e.g., a digital mass bit counter).

In step S160, the low voltage manager 1450 performs a planned read operation because the current voltage level of the power supply voltage VCC corresponds to the normal voltage range (ΔNVCC, see FIG. 4) higher than the reference voltage Vref.

In step S170, the low voltage manager 1450 determines whether the current voltage level of the power supply voltage VCC falls within the low voltage range ΔLVCC that is lower than the reference voltage Vref and higher than the lower limit voltage VCC_d (see FIG. 4). For example, the low voltage manager 1450 may determine whether the voltage level of the power supply voltage VCC is higher than the lower limit voltage VCC_d by comparing the second sensing data SD2 and the lower limit voltage VCC_d. If the level of the current power supply voltage VCC is determined to be lower than the reference voltage Vref and higher than the lower limit voltage VCC_d (‘Yes’ direction), the low voltage manager 1450 determines the low voltage state (Low_VCC), and the operation moves to step S180. On the other hand, if it is determined that the level of the current power supply voltage VCC is below the lower limit voltage VCC_d (‘No’ direction), the low voltage manager 1450 may perform another reset operation other than the core control operation, and the operation moves to step S190. For example, when the voltage level of the power supply voltage VCC is below the low voltage range ΔLVCC, a reset operation may be performed.

In step S180, the low voltage manager 1450 maintains the voltage of the selected word line WL at the read pass voltage Vread level. For example, the low voltage manager 1450 may extend a time period (i.e., duration) for which the selected word line WL is maintained at the read pass voltage Vread level. Then, the time for the charge to discharge to the ground side in the boosted channel of the selected cell string can be increased. Accordingly, hot-carrier-injection (HCI) that may occur in the channel of the selected cell string can be prevented. For example, the low voltage manager 1450 may perform the core control operation in step S180 when the voltage level of the power supply voltage VCC is lower than the reference voltage Vref.

In step S190, the low voltage manager 1450 may perform other operations such as device reset or trimming rather than core control operations. According to embodiments of the present disclosure described above, the low voltage manager 1450 maintains the voltage of the selected word line WL at the read pass voltage Vread level when the level of the current power supply voltage VCC corresponds to a low voltage state (Low_VCC). In this case, a path for removing charge from the channel of the NAND cell string can be effectively formed during the pre-pulse section of the read operation. Accordingly, the effect of reducing or preventing hot-carrier-injection (HCI) is provided.

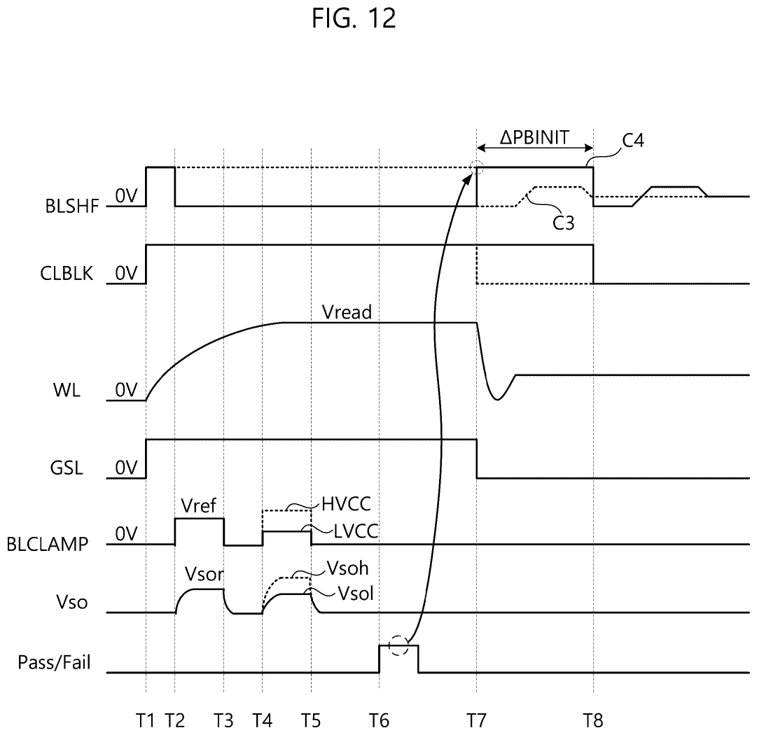

FIG. 12 is a timing diagram showing core control operation according to further embodiments of the present disclosure. Referring to FIG. 12, in the page buffer initialization period PBINIT, whether the power supply voltage (VCC) is in a low voltage state (Low_VCC) can be detected through first sensing and second sensing (i.e., through first sensing and second sensing operations). When a low voltage state (Low_VCC) is detected, the high level section of the bit line shut-off signal BLSHF can be extended in the page buffer initialization period PBINIT to block the hot-carrier-injection (HCI).

Referring to FIGS. 5, 6, and 12, at time T1, the page buffer initialization section PBINIT for the read operation begins. To initialize the page buffer PB0, the bit line shut-off signal BLSHF and the bit line connection control signal CLBLK transition to high level ‘H’. Then, the fifth and sixth transistors NM5 and NM6 connected in series between the bit line selection transistor TR_hv and the sensing node SO will be turned on. In addition, a read pass voltage Vread to remove the channel charge of the selected NAND cell string begins to be provided to the selected word line WL. Accordingly, the voltage of the selected word line WL begins to rise. At this time, the ground selection signal GSL of the selected NAND cell string is maintained at a high level, so that the charge of the boosted channel can be continuously discharged to ground.

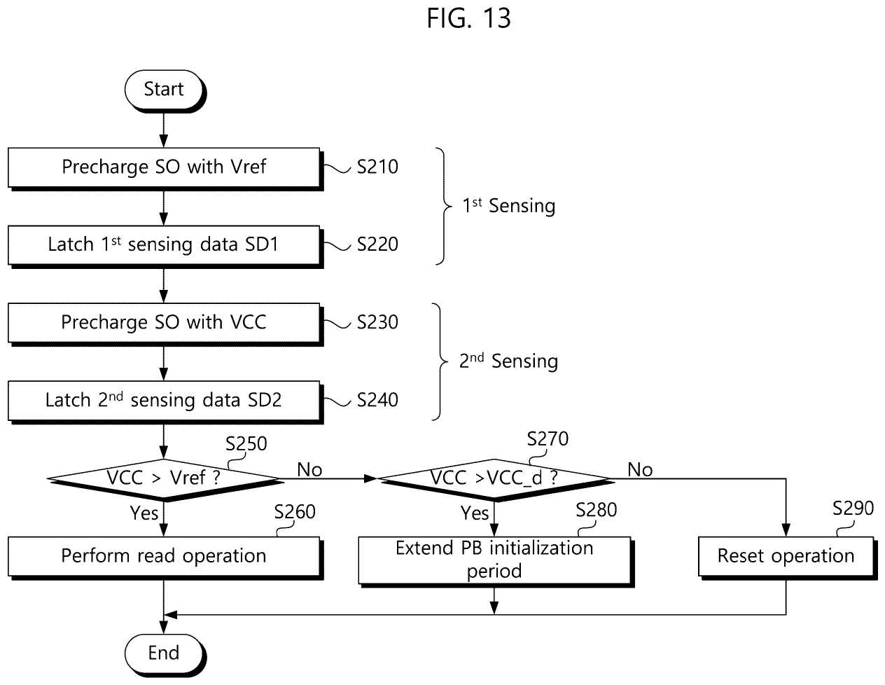

At time T2, the bit line shut-off signal BLSHF transitions to low level ‘L’ and the first sensing mode starts. The bit line BL and the page buffer PB0 are blocked by the transition of the bit line shut-off signal BLSHF to the low level ‘L’. To execute the first sensing mode, the bit line clamp signal BLCLAMP is provided at the reference voltage Vref level. The sensing node SO (e.g., the sensing node voltage Vso) will be precharged to the reference sensing node voltage Vsor by the bit line clamp signal BLCLAMP. The sensing node SO precharged with the reference sensing node voltage Vsor is latched by the sensing latch SL. At this time, the latched data may be stored as first sensing data SD1 (e.g., see FIG. 13). The first sensing mode ends at time T3.

At time T4, the second sensing mode starts while the bit line shut-off signal BLSHF is maintained at the low level ‘L’. To execute the second sensing mode, the bit line clamp signal BLCLAMP is generated with a value corresponding to the level of the current power supply voltage VCC. For example, when the level of the current power supply voltage VCC is higher than the reference voltage Vref, the bit line clamp signal BLCLAMP may be generated at a first voltage HVCC level higher than the reference voltage Vref. On the other hand, when the level of the current power supply voltage VCC is lower than the reference voltage Vref, the bit line clamp signal BLCLAMP may be generated at a second voltage LVCC level that is lower than the reference voltage Vref.

In the second sensing mode, when the bit line clamp signal BLCLAMP is generated at the first voltage HVCC level, the sensing node SO (e.g., the sensing node voltage Vso) will be precharged with the first sensing node voltage Vsoh. On the other hand, when the bit line clamp signal BLCLAMP is generated at a relatively low second voltage LVCC level, the sensing node SO (e.g., the sensing node voltage Vso) will be precharged with the second sensing node voltage Vsol. The state of the sensing node SO precharged with the first sensing node voltage Vsoh or the second sensing node voltage Vsol is latched by the sensing latch SL. At this time, the latched data may be stored as second sensing data SD2. The second sensing mode ends at time T5.

At time T6, the state of the current power supply voltage VCC is determined by comparing the first sensing data SD1 and the second sensing data SD2. That is, a pass/fail determination is made to determine whether the current level of the power supply voltage VCC corresponds to the low voltage state (Low_VCC). The first sensing data SD1 is obtained as a result of the first sensing mode that precharges and senses the sensing node SO using the bit line clamp signal BLCLAMP of the reference voltage Vref. And, the second sensing data SD2 is acquired as a result of second sensing mode that precharges and senses the sensing node SO using a bit line clamp signal BLCLAMP corresponding to the level of the current power supply voltage VCC. The low voltage manager (1450, see FIGS. 1 and 3) uses the fail bit count FBC or digital mass bit count DMBC technique for the first sensing data SD1 and the second sensing data SD2 to determine the low voltage state (Low_VCC). If the level of the current power supply voltage VCC corresponds to a low voltage state (Low_VCC), the low voltage manager 1450 determines the page buffer initialization PBINIT as Fail. On the other hand, if the level of the current power supply voltage VCC does not correspond to the low voltage state (Low_VCC), the low voltage manager 1450 determines the current power supply voltage VCC state as Pass.

At time T7, the low voltage manager 1450 may activate a core control operation when the level of the current power supply voltage VCC corresponds to the low voltage state (Low_VCC). That is, the level of the bit line shut-off signal BLSHF may transition to the high level ‘H’. In particular, the low voltage manager 1450 may extend the high level section of the bit line shut-off signal BLSHF by the additional initialization section ΔPBINIT. In addition, the bit line connection control signal CLBLK may also be maintained at a high level ‘H’ during the additional initialization section ΔPBINIT. In other words, to perform the core control operation, the low voltage manager 1450 may extend the page buffer initialization period PBINIT to have the additional initialization section ΔPBINIT by transitioning the voltage level of the bit line shut-off signal BLSHF to the high level ‘H’ (e.g., from a ‘O’ to a ‘1’). The extension of the additional initialization section ΔPBINIT of the bit line shut-off signal BLSHF is shown in the curve C4 as a solid line. During the additional initialization section ΔPBINIT of the bit line shut-off signal BLSHF, the fifth and sixth transistors NM5 and NM6 are turned on, and the channel charge of the NAND cell string boosted through the bit line BL may be discharged to the sensing node SO side of the buffer. In other words, to perform the core control operation, the low voltage manager 1450 may electrically connect the sensing node SO of the page buffer PB0 to the bit line BL (e.g., to discharge the channel charge of the NAND cell string) by transitioning the bit line shut-off signal BLSHF to the high level ‘H’ and extending the page buffer initialization period PBINIT to have the additional initialization section ΔPBINIT. Therefore, as the boosted channel voltage drops, hot-carrier-injection (HCI) can be reduced or prevented.

On the other hand, when the level of the current power supply voltage VCC corresponds to a normal state higher than the reference voltage Vref, the level of the bit line shut-off signal BLSHF transitions to the low level ‘L’ at time T7. The waveform of this bit line shut-off signal BLSHF is shown in the curve C3 as a dotted line. In addition, the bit line connection control signal CLBLK may also transition to low level ‘L’ at time T7. According to the low level transition of the bit line shut-off signal BLSHF and the bit line connection control signal CLBLK, the fifth and sixth transistors NM5 and NM6 are turned off, and the page buffer PB0 (e.g., the sensing node SO of the page buffer PB0) is electrically isolated from the bit line BL.

FIG. 13 is a flowchart showing the power supply voltage level detection and core control operation according to further embodiments of the present disclosure. Referring to FIGS. 1, 3-6, 12, and 13, the nonvolatile memory device 1000 can identify whether a power supply voltage VCC is in a low voltage state (Low_VCC) by performing first sensing and second sensing (i.e., first sensing and second sensing operations) on a sensing node SO of a page buffer circuit 1300. In addition, the nonvolatile memory device 1000 may extend the high level section of the bit line shut-off signal BLSHF by the additional initialization section ΔPBINIT when the power supply voltage VCC corresponds to a low voltage state (Low_VCC). Accordingly, the nonvolatile memory device 1000 can reduce or prevent hot-carrier-injection (HCI) caused by a decrease in the power supply voltage VCC.

In step S210, the bit lines BL and the page buffers PB0, PB1, . . . , PBk-1 are electrically blocked by the transition of the bit line shut-off signal BLSHF to the low level ‘L’. To execute the first sensing mode, the reference voltage Vref is provided as the bit line clamp signal BLCLAMP. The sensing node SO is precharged by the bit line clamp signal BLCLAMP at the reference voltage Vref level. That is, the sensing nodes SO of the page buffers PB0, PB1, . . . , PBk-1 may be precharged based on the reference voltage Vref. For example, the bit line clamp signal BLCLAMP may be generated corresponding to the reference voltage Vref, and the sensing nodes SO of the page buffers PB0, PB1, . . . , PBk-1 may be precharged based on the bit line clamp signal BLCLAMP.

In step S220, the sensing node SO of each of the page buffers PB0, PB1, . . . , PBk-1 precharged by the reference voltage Vref is sensed and latched by the sensing latch SL. At this time, the latched data may be stored as first sensing data SD1. That is, the sensing nodes SO of the page buffers PB0, PB1, . . . , PBk-1 may be latched to obtain the first sensing data SD1. For example, the low voltage manager 1450 may control the page buffers PB0, PB1, . . . , PBk-1 to precharge and sense the sensing nodes SO based on the reference voltage Vref to obtain the first sensing data SD1. Steps S210 and S220 constitute a first sensing mode.

In step S230, to execute a second sensing mode, the bit line clamp signal BLCLAMP is generated with a value corresponding to the level of the current power supply voltage VCC. For example, when the level of the current power supply voltage VCC is higher than the reference voltage Vref, the bit line clamp signal BLCLAMP may be generated at a first voltage HVCC level higher than the reference voltage Vref. On the other hand, when the level of the current power supply voltage VCC is lower than the reference voltage Vref, the bit line clamp signal BLCLAMP may be generated at a second voltage LVCC level that is lower than the reference voltage Vref. The sensing node SO is precharged by the bit line clamp signal BLCLAMP corresponding to the level of the current power supply voltage VCC. That is, the sensing nodes SO of the page buffers PB0, PB1, . . . , PBk-1 may be precharged based on the power supply voltage VCC. For example, the bit line clamp signal BLCLAMP may be generated corresponding to the power supply voltage VCC (e.g., at the first voltage HVCC or the second voltage LVCC), and the sensing nodes SO of the page buffers PB0, PB1, . . . , PBk-1 may be precharged based on the bit line clamp signal BLCLAMP.

In step S240, the data corresponding to the sensing node SO of each of the page buffers PB0, PB1, . . . , PBk-1 precharged by the bit line clamp signal BLCLAMP corresponding to the level of the current power supply voltage VCC is latched into the sensing latch SL. At this time, the latched data may be stored as second sensing data SD2. That is, the sensing nodes SO of the page buffers PB0, PB1, . . . , PBk-1 may be latched to obtain the second sensing data SD2. For example, the low voltage manager 1450 may control the page buffers PB0, PB1, . . . , PBk-1 to precharge and sense the sensing nodes SO based on the power supply voltage VCC to obtain the second sensing data SD2. Steps S230 and S240 constitute a second sensing mode.

In step S250, the low voltage manager 1450 determines the state of the current power supply voltage VCC using the first sensing data SD1 and the second sensing data SD2. That is, the low voltage manager 1450 determines whether the level of the current power supply voltage VCC is higher than the reference voltage Vref (e.g., based on a comparison between the first sensing data SD1 and the second sensing data SD2). For example, the low voltage manager 1450 may perform a low voltage detection operation by comparing the first sensing data SD1 and the second sensing data SD2 to determine whether the voltage level of the power supply voltage VCC is lower than the reference voltage Vref. If it is determined that the level of the current power supply voltage VCC is higher than the reference voltage Vref (‘Yes’ direction), the operation moves to step S260. On the other hand, if it is determined that the level of the current power supply voltage VCC is not higher than the reference voltage Vref (‘No’ direction), the operation moves to step S270. For example, the low voltage manager 1450 may compare the first sensing data SD1 and the second sensing data SD2 using a fail bit count technique (e.g., a fail bit counter) or a digital mass bit count technique (e.g., a digital mass bit counter).

In step S260, the low voltage manager 1450 performs a read operation because the current level of the power supply voltage VCC corresponds to the normal voltage range (ΔNVCC, see FIG. 4) higher than the reference voltage Vref.

In step S270, the low voltage manager 1450 determines whether the current level of the power supply voltage VCC falls within the low voltage range ΔLVCC that is lower than the reference voltage Vref and higher than the lower limit voltage VCC_d (see FIG. 4). For example, the low voltage manager 1450 may determine whether the voltage level of the power supply voltage VCC is higher than the lower limit voltage VCC_d by comparing the second sensing data SD2 and the lower limit voltage VCC_d. If the level of the current power supply voltage VCC is determined to be lower than the reference voltage Vref and higher than the lower limit voltage VCC_d (‘Yes’ direction), the low voltage manager 1450 determines the low voltage state (Low_VCC), and the operation moves to step S280. On the other hand, if it is determined that the level of the current power supply voltage VCC is below the lower limit voltage VCC_d (‘No’ direction), the low voltage manager 1450 may perform another reset operation other than the core control operation, and the operation moves to step S290. For example, when the voltage level of the power supply voltage VCC is below the low voltage range ΔLVCC, a reset operation may be performed.

In step S280, the low voltage manager 1450 may extend the high level section of the bit line shut-off signal BLSHF in the page buffer initialization period by the additional initialization section ΔPBINIT. As the high level section of the bit line shut-off signal BLSHF extends during the additional initialization section ΔPBINIT, the charge of the boosted channel of the NAND cell string through the bit line BL can be discharged toward the sensing node SO of the page buffer PB0. In other words, to perform the core control operation, the low voltage manager 1450 may electrically connect the sensing nodes SO of the page buffers PB0, PB1, . . . , PBk-1 to the bit lines BL by transitioning the bit line shut-off signal BLSHF to the high level ‘H’ and extending the page buffer initialization period PBINIT to have the additional initialization section ΔPBINIT. Accordingly, the boosted channel voltage can be lowered, and hot-carrier-injection (HCI) can be reduced or prevented. For example, the low voltage manager 1450 may perform the core control operation in step S280 when the voltage level of the power supply voltage VCC is lower than the reference voltage Vref.

In step S290, the low voltage manager 1450 may perform other operations such as device reset or trimming rather than the core control operation.

According to further embodiments of the present disclosure described above, the low voltage manager 1450 can extend the high level section of the bit line shut-off signal BLSHF when the level of the current power supply voltage VCC corresponds to a low voltage state (Low_VCC). As the high level section of the bit line shut-off signal BLSHF is extended, the channel potential of the NAND cell string may be lowered. Accordingly, it is possible to reduce or prevent hot-carrier-injection (HCI) due to relatively high channel potential.

The above are example embodiments for carrying out the present disclosure. In addition to the above-described embodiments, the present disclosure is intended to encompass simple design changes or easily changeable embodiments. In addition, the present disclosure may include techniques that can be easily modified and implemented using the example embodiments. Therefore, the scope of the present disclosure should not be limited to the above-described embodiments, and should be defined by the claims and equivalents of the claims of the present disclosure as well as the claims to be described later.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms “first”, “second”, “third”, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure.

What is claimed is:

1. A method of operating a non-volatile memory device, comprising:
precharging sensing nodes of a plurality of page buffers based on a reference voltage and latching the sensing nodes to obtain first sensing data;
precharging the sensing nodes of the plurality of page buffers based on a power supply voltage and latching the sensing nodes to obtain second sensing data; and
comparing the first sensing data and the second sensing data to determine whether a voltage level of the power supply voltage is lower than the reference voltage.

2. The method of claim 1, further comprising generating a bit line clamp signal corresponding to at least one of the reference voltage or the power supply voltage, wherein the sensing nodes are precharged based on the bit line clamp signal.

3. The method of claim 2, further comprising dividing the power supply voltage using a voltage divider to generate a divided power supply voltage, wherein the bit line clamp signal corresponds to the divided power supply voltage.

4. The method of claim 1, wherein the first sensing data and the second sensing data are compared using a fail bit count technique.

5. The method of claim 1, wherein the first sensing data and the second sensing data are compared using a digital mass bit count technique.

6. The method of claim 1, further comprising performing a core control operation to lower a channel potential of a selected NAND cell string when the voltage level of the power supply voltage is lower than the reference voltage.

7. The method of claim 6, wherein the core control operation includes extending a time period for which a voltage of a selected word line is maintained at a read pass voltage level.

8. The method of claim 6, wherein the core control operation includes extending a page buffer initialization period by transitioning a voltage level of a bit line shut-off signal to a high level.

9. A non-volatile memory device, comprising:
a cell array including a plurality of NAND cell strings electrically connected to bit lines;
a row decoder configured to select a row of the cell array in response to an address;
a page buffer circuit including a plurality of page buffers configured to sense memory cells of the selected row through the bit lines; and
a control circuit configured to:
control the plurality of page buffers to precharge and sense sensing nodes of the plurality of page buffers based on a reference voltage to obtain first sensing data;
control the plurality of page buffers to precharge and sense the sensing nodes based on a power supply voltage to obtain second sensing data;
perform a low voltage detection operation to determine whether a voltage level of the power supply voltage is lower than the reference voltage based on a comparison between the first sensing data and the second sensing data; and
perform a core control operation to lower a channel potential of at least one of the plurality of NAND cell strings when the voltage level of the power supply voltage is lower than the reference voltage.

10. The device of claim 9, wherein each of the plurality of page buffers includes a precharge level generator configured to generate a bit line clamp signal that corresponds to at least one of the reference voltage or the power supply voltage.

11. The device of claim 10, wherein the precharge level generator comprises:
a reference voltage generator configured to generate the reference voltage;
a divided voltage generator configured to generate a divided power supply voltage by dividing the power supply voltage; and
a selection circuit configured to select the reference voltage or the divided power supply voltage to generate the bit line clamp signal.

12. The device of claim 9, wherein the control circuit is configured to control the plurality of page buffers to perform a first sensing operation for sensing the sensing nodes precharged based on the reference voltage, and a second sensing operation for sensing the sensing nodes precharged based on the power supply voltage.

13. The device of claim 12, wherein the control circuit is configured to compare the first sensing data, which is latched as a result of the first sensing operation, and the second sensing data, which is latched as a result of the second sensing operation, to detect a low voltage state in which the voltage level of the power supply voltage is lower than the reference voltage.

14. The device of claim 13, wherein the control circuit includes at least one of a fail bit counter or a digital mass bit counter that is configured to count a number of bit transitions of the first sensing data and the second sensing data.

15. The device of claim 13, wherein, in the core control operation, the control circuit is configured to extend a time period for which a selected word line is maintained at a read pass voltage level.

16. The device of claim 13, wherein, in the core control operation, the control circuit is configured to electrically connect the sensing nodes to the bit lines during a page buffer initialization period.

17. The device of claim 16, wherein, in the core control operation, the control circuit is configured to electrically connect the sensing nodes to the bit lines by transitioning a bit line shut-off signal to a high level and extending the page buffer initialization period.

18. A method of operating a non-volatile memory device, comprising:
precharging sensing nodes of a plurality of page buffers based on a reference voltage;
latching data of the sensing nodes precharged based on the reference voltage to obtain first sensing data;
precharging the sensing nodes of the plurality of page buffers based on a power supply voltage;
latching data of the sensing nodes precharged based on the power supply voltage to obtain second sensing data;
comparing the first sensing data and the second sensing data to determine whether a voltage level of the power supply voltage is lower than the reference voltage; and
performing a core control operation to lower a channel potential of a selected NAND cell string when the voltage level of the power supply voltage is lower than the reference voltage.

19. The method of claim 18, further comprising determining whether the voltage level of the power supply voltage is higher than a lower limit voltage by comparing the second sensing data and the lower limit voltage,
wherein the core control operation is performed when the voltage level of the power supply voltage is lower than the reference voltage and higher than the lower limit voltage, and
wherein the core control operation includes extending a time period for which a voltage of a selected word line is maintained at a read pass voltage.

20. The method of claim 18, wherein the core control operation includes extending a page buffer initialization period by transitioning a voltage level of a bit line shut-off signal to a high level.
